(19) United States
(12) Patent Application Publication
(10) Pub. No.: US 2009/0032946 A1
(43) Pub. Date: Feb. 5, 2009

(54) INTEGRATED CIRCUIT

(76) Inventor: Soo Gil Park, Radebeul (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/832,404

(22) Filed: Aug. 1, 2007

(51) Int. Cl. H01L 23/52; H01L 23/488

(52) U.S. Cl. 257/738; 257/777; 257/786; 257/E23.079; 257/E23.023

(57) ABSTRACT

Integrated circuits and methods for making integrated circuits having a base layer, a side substrate, a circuit substrate and a connection. A bottom face of the base layer is disposed on the side substrate. The side substrate includes a first contact field, at least a second contact field, and a signal line. The first contact field is arranged on the bottom face in an area of an opening of the base layer, the second contact field is arranged on another face of the side substrate, and the signal line connects the first contact field to the second contact field. The circuit substrate is disposed on the base layer and alongside the side substrate. The connection connects the circuit substrate to the second contact field of the side substrate.

### BACKGROUND OF THE INVENTION

1. Field of the Invention

The present invention relates to the field of integrated circuits.

2. Description of the Related Art

Integrated circuits may include typically electronic data memories, microprocessors, programmable logic devices, integrated digital and/or analogue circuitries.

The integrated circuits are formed on substrates using a variety of fabrication techniques. Individual substrates may be of different type, hence comprising different electronic and/or optical circuitries, or a stack may also include two or more identical substrates of the same type. This may be of advantage, for example, in the case of electronic data memory devices, since several memory array chips may be stacked and grouped in order to increase the overall storage capacity of the device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B show schematic views of an integrated circuit according to a first embodiment of the present invention;

FIG. 1C shows a schematic view of an integrated circuit according to a second embodiment of the present invention;

FIGS. 2A through 2D show schematic views of integrated circuits according to a third, fourth, fifth, and sixth embodiment of the present invention;

FIGS. 3A through 3F show schematic views of integrated circuits according to a seventh, eighth, ninth, tenth, eleventh, and twelfth embodiment of the present invention;

FIGS. 4A through 4C show schematic views of integrated circuits in conjunction with circuit boards according to a thirteenth, fourteenth, and fifteenth embodiment of the present invention;

FIGS. 5A through 5C show schematic top views of integrated circuits according to a sixteenth, seventeenth, and eighteenth embodiment of the present invention; and

FIGS. 6A through 6C show schematic bottom views of the integrated circuits according to the sixteenth, the seventeenth, and the eighteenth embodiment of the present invention.

### DETAILED DESCRIPTION OF THE PREFERRED EMBODIMENT

Integrated circuits may include typically electronic data memories, microprocessors, programmable logic devices, integrated digital and/or analogue circuitries. Examples for electronic data memories include DRAM devices, flash RAM devices, SRAM devices, PCRAM devices, MRAM devices, CBRAM devices, and other volatile and non-volatile memory devices.

Individual substrates may be of different type, hence comprising different electronic and/or optical circuitries, or a stack may also include two or more identical substrates of the same type. This may be of advantage, for example, in the case of electronic data memory devices, since several memory array chips may be stacked and grouped in order to increase the overall storage capacity of the device.

Upon stacking several substrates or chips, naturally, the height of a corresponding substrate stack increases. Due to a minimum substrate height or thickness which may be required, the reduction of this thickness of an individual substrate or chip may be limited. Hence, those limitations may pose difficulties upon manufacturing integrated devices and meeting the requirement of not exceeding a given maximum height of the completed device. A reason why a single substrate or chip may require a minimum height may lie in a substrate warpage, electrical and/or optical leakage, electrical and/or optical properties, high frequency response and/or interference.

Various embodiments of the present invention may provide particular advantages for an improved integrated circuit and an improved memory device.

One embodiment of the present invention includes an integrated circuit having a base layer, the base layer comprising at least an opening; a side substrate, the side substrate being arranged on the base layer with a bottom face of the side substrate and comprising a first contact field, at least a second contact field, and a signal line, the first contact field being arranged on the bottom face in an area of the opening of the base layer, the second contact field being arranged on another face of the side substrate, and the signal line connecting the first contact field to the second contact field; a circuit substrate, the circuit substrate being arranged on the base layer and alongside the side substrate; and a connection, the connection connecting the circuit substrate to the second contact field of the side substrate.

Another embodiment of the present invention includes an integrated circuit having a base layer, the base layer comprising at least an opening; a side substrate comprising an opening, the side substrate being arranged on the base layer with a bottom face of the side substrate and comprising a first contact field, at least a second contact field, and a signal line, the first contact field being arranged on the bottom face in an area of the opening of the base layer, the second contact field being arranged on another face of the side substrate, and the signal line connecting the first contact field to the second contact field; a substrate stack comprising at least two circuit substrates, the substrate stack being arranged on the base layer and inside the opening of the side substrate; and a connection, the connection connecting a circuit substrate of the substrate stack to the second contact field of the side substrate.

Another embodiment of the present invention includes an integrated memory device having a base layer, the base layer comprising at least an opening; a side substrate comprising an opening, the side substrate being arranged on the base layer with a bottom face of the side substrate and comprising a contact field, a first bond pad, and a signal line, the contact field being arranged on the bottom face in an area of the opening of the base layer, the first bond pad being arranged on a top face of the side substrate, and the signal line connecting the contact field to the first bond pad; a chip stack comprising at least two memory chips substrates, the chip stack being arranged on the base layer and inside the opening of the side substrate, a memory chip of the chip stack comprising a second bond pad on a top face; a bond wire, the bond wire connecting the first bond pad of the side substrate to the second bond pad of the memory chip of the chip stack; and an encapsulation, the encapsulation being arranged adjacent to the chip stack, the side substrate, the base layer, and the bond wire.

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit equally effective embodiments.

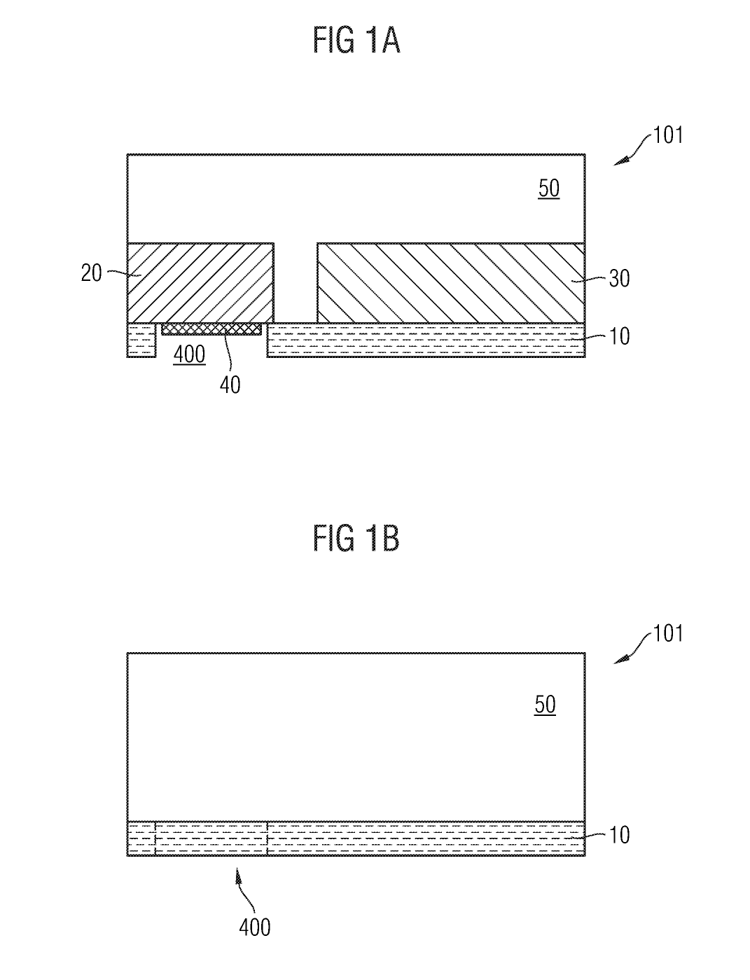

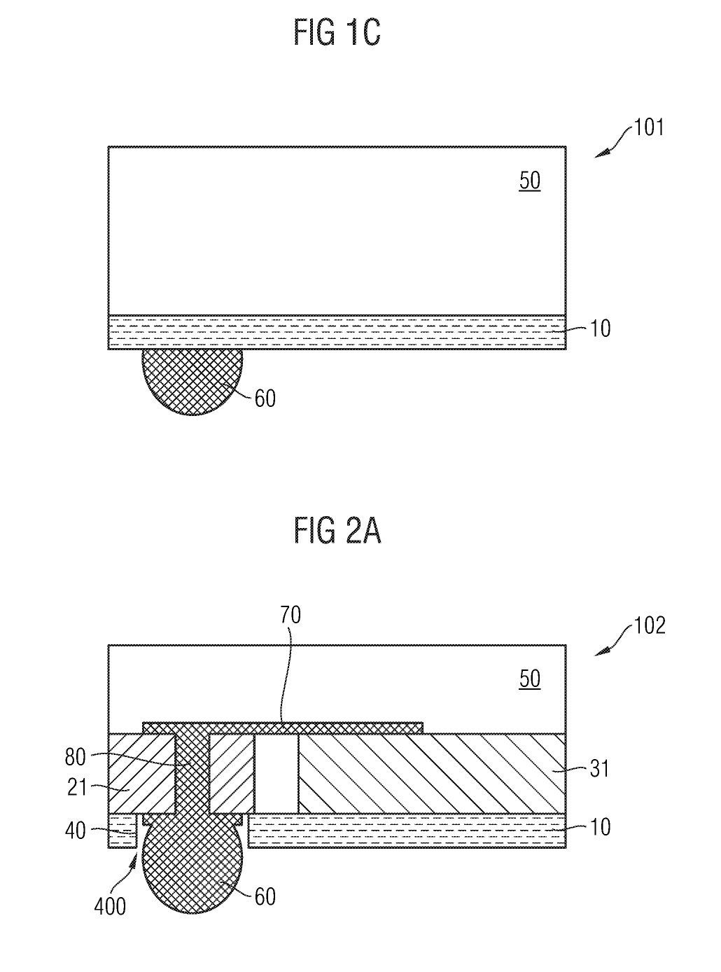

FIG. 1A shows a schematic cross-sectional view of an integrated circuit 101 or a respective section thereof, according to this first embodiment of the present invention. The integrated circuit 101 comprises a base layer 10, a side substrate 20, and a circuit substrate 30. The side substrate 20 comprises a contact pad 40 on a bottom side of the side substrate 20. The core of a chip carrier substrate may be packed into the side substrate 20. The side substrate 20 is arranged on the base layer 10.

The base layer 10 comprises an opening 400, which may be arranged in conjunction with the contact field 40 of the side substrate 20. The contact field 40 and the opening 400 may, at least in part, overlap, such that the contact field 40 is accessible through the opening 400. The opening 400 may also be greater than the area of the contact field 40, such that the contact field 40 is separated from the base layer 10, and, therefore, the contact field 40 may be electrically isolated from the base layer 10. The base layer 10 may comprise a metal layer, such as a copper layer, which may provide mechanical stability to the arrangement, an electric connection, and/or a thermal conduction. In this way, the base layer 10 may act as a substrate carrier or chip carrier. For such purposes, the metal layer may be structured and may comprise further openings and/or signal lines. The base layer 10 may furthermore comprise a cover layer which may, at least in part, cover a copper layer. This may provide an improved adhesion between a metal, such as the copper, and the side substrate and/or the circuit substrate.

A circuit substrate 30 is arranged on the base layer 10 alongside the side substrate 20. The circuit substrate 30 may comprise a single circuit substrate and/or a stack of several circuit substrates. A circuit substrate may be or comprise a circuit chip. An integrated circuit package may comprise a mold material 50 (also referred to herein as “encapsulation material”), which, at least in part, covers the circuit substrate 30 and the side substrate 20. The mold material 50 may also reach down to the base layer 10 and may fill any space between the side substrate 20 and the circuit substrate 30. The mold material 50 may comprise a resin material, a ceramic material, or the like.

The circuit substrate 30 is connected to the contact field 40 by means of the side substrate 20. Hence, an electrical connection to the circuit substrate 30 or functional entities thereof may be established by means of contacting the contact field 40. Functional elements of the circuit substrate 30 may include resistors, transistors, capacitors, conductors, dielectrics, light-emitting diodes, diodes, semiconductor lasers, light sensors, isolators, and/or other entities as they are known from the technology of manufacturing highly integrated devices.

FIG. 1B shows a schematic side view of the integrated circuit 101 according to the first embodiment of the present invention. According to this embodiment, the mold material 50 encapsulates both the side substrate 20 and the circuit substrate 30. The base layer 10 comprises the openings 400 in order to allow an electrical connection to the integrated circuit 101 by means of contacting the respective contact fields.

FIG. 1C shows a schematic side view of an integrated circuit according to a second embodiment of the present invention. Accordingly, the integrated circuit 101 is shown in conjunction with a solder ball 60, which may be arranged on a contact field, such as the contact field 40. The solder ball 60 may establish an electric contact to the integrated circuit 101 by means of arranging the integrated circuit 101 on, for example, a circuit board, such as a printed circuit board (PCB), and soldering the solder ball 60 to a corresponding contact field of such a circuit board and/or circuit system. Soldering may be effected by means of wave soldering, infrared soldering, laser soldering, reflow soldering, and/or any other soldering techniques as they are known from the technology of manufacturing integrated circuit systems.

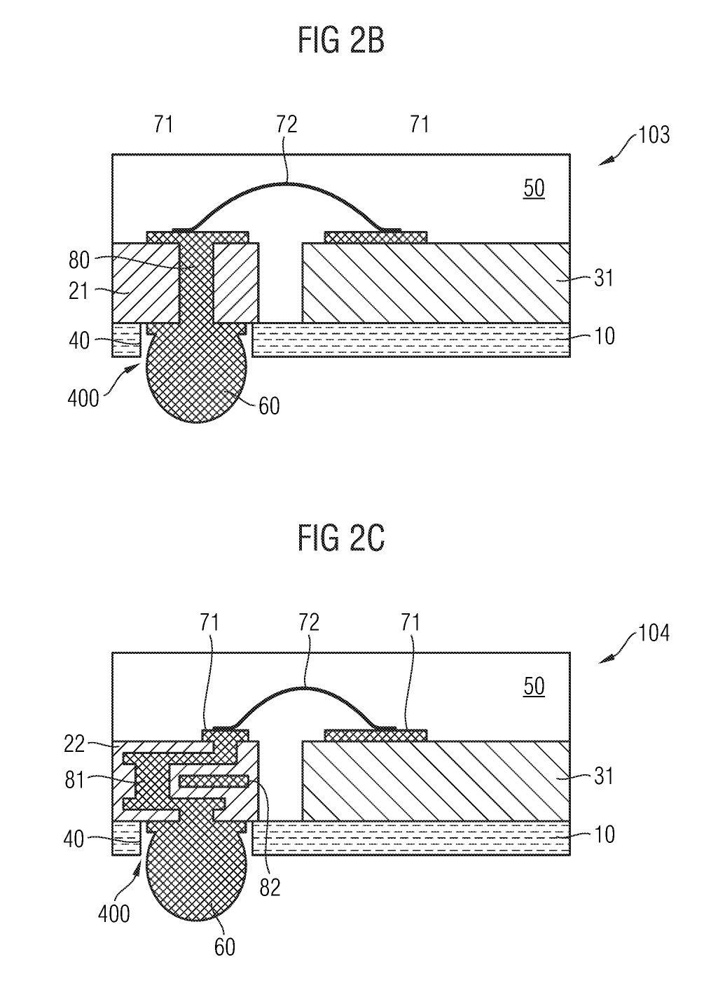

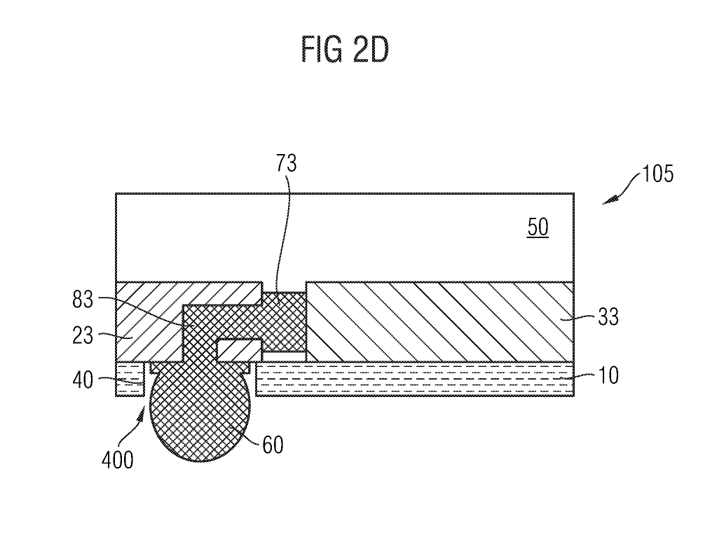

FIG. 2A shows a schematic cross-sectional view of an integrated circuit according to a third embodiment of the present invention. An integrated circuit 102 comprises a side substrate 21 and a circuit substrate 31 on the base layer 10. The base layer 10 comprises the opening 400, in which is arranged the contact field 40 on a bottom surface of the side substrate 21. A solder ball 60 is arranged on the contact field 40, in order to allow for an electric connection to the integrated circuit 102 from an external circuitry.

A connection 70 connects the circuit substrate 31 to a via 80. The via 80 is arranged inside the side substrate 21 and connects the connection 70 to the contact field 40. The via 80 may be a filled via and may comprise a solder material, a conducting material, a metal, a doped semiconductor, a semiconductor, carbon, the material of the solder ball 60, and/or a combination thereof. The connection 70 may comprise a conductive material, such as copper, a solder material, silver, conductive adhesive, conductive paint, and the like. The connection 70 may be provided by printing, depositing, and/or lithographic structuring.

FIG. 2B shows a schematic cross-sectional view of an integrated circuit according to a fourth embodiment of the present invention. An integrated circuit 103 comprises the side substrate 21, the base layer 10, and the circuit substrate 31. According to this embodiment of the present invention, a bond pad 71 is arranged on a top surface of the circuit substrate 31. A further bond pad 71 is arranged on a top surface of the side substrate 21, which is connected to the via 80.

A bond connection, comprising, for example, a bond wire 72, connects the two bond pads 71 and, hence, establishes an electrical connection of the solder ball 60 to the circuit substrate 31 via the contact field 40, the via 80, the bond pad 71 on the side substrate 21, the bond wire 72, and the bond pad 71 on the circuit substrate 31. The mold material 50, according to this embodiment of the present invention, covers and/or surrounds the bond wire 72, which is, in this way, protected from mechanical, physical, chemical and/or other influences.

In the case of the circuit substrate 31 being connected to the side substrate 21 by means of a bond wire, the height of the side substrate 21 may be chosen such to be approximately equal to the height of the circuit substrate 32. Nevertheless, the corresponding heights of the side substrate 21 and the circuit substrate 32 may also differ, since bonding techniques also allow for a substantial difference between the heights of the corresponding starting pad and target pad.

FIG. 2C shows a schematic cross-sectional view of an integrated circuit according to a fifth embodiment of the present invention. Elements and entities which have already been described in conjunction with an embodiment of the present invention are denoted by same reference numbers. According to this embodiment, the side substrate 22 comprises a redistribution layer, which redistributes, in general, more than one signal line between bond pads 71, being arranged on a top surface of the side substrate 22, and corresponding contact fields 40, being arranged on a bottom surface of the side substrate 22.

A first signal line 81 comprises vertical vias and/or horizontal conductive traces such to circum navigate a second signal line 82. Hence, the side substrate 22 may comprise one, two, or more trace layers which are interconnected by means of vias. In this way, it may be possible, to reroute an electrical signal from a given bond pad 71 to a corresponding contact field 40, although the bond pad 71 and the corresponding contact field 40 are arranged at different positions within a plane of the side substrate 22 and/or although further signal lines obstruct a direct connection of the two.

Furthermore, it may be possible to connect a plurality of bond pads 71 on a top surface to a plurality of contact fields 40 on a bottom surface whilst allowing for an arbitrary connection scheme amongst the pads and fields. In this way, the number of individual connections to the circuit substrate 32 may be increased and the density of interconnections on the bottom surface may be optimized in order to allow a minimized foot print of the integrated circuit 104.

FIG. 2D shows a schematic cross-sectional view of an integrated circuit according to a sixth embodiment of the present invention. An integrated circuit 105 comprises a circuit substrate 33 and a side substrate 23, being arranged on the base layer 10. The side substrate 23 comprises a signal via 83 which allows an electrical connection from the contact field 40, which is arranged on the bottom surface of the side substrate 23, to a side face of the circuit substrate 33. A connection 73 connects the signal via 83 of the side substrate 23 to the circuit substrate 33. The circuit substrate 33 may comprise a corresponding contact pad on a side face such to connect to the connection 73.

Furthermore, the circuit substrate 33 may comprise more than one individual substrate, such as a substrate stack. The circuit substrate 33 or a corresponding substrate stack may comprise a trace layer or a redistribution layer, that, in turn, comprises signal lines. Such signal lines may extend to the side face of the substrate 33 and a cross-section of such a signal line may be prepared for providing a contact field for interconnection with the connection 73. The connection 73 may comprise a solder material, a conductive adhesive, a flexible element, and/or a mechanical contact. According to this embodiment of the present invention, the overall height of the integrated circuit 105 may be further reduced, since no connection between the side substrate 23 and the circuit substrate 33 is necessary above a top surface of the side substrate 23 and/or above a top surface of the circuit substrate 33. The height and the amount of the mold material 50 may be correspondingly reduced. This may be an advantage when the effective device height is critical.

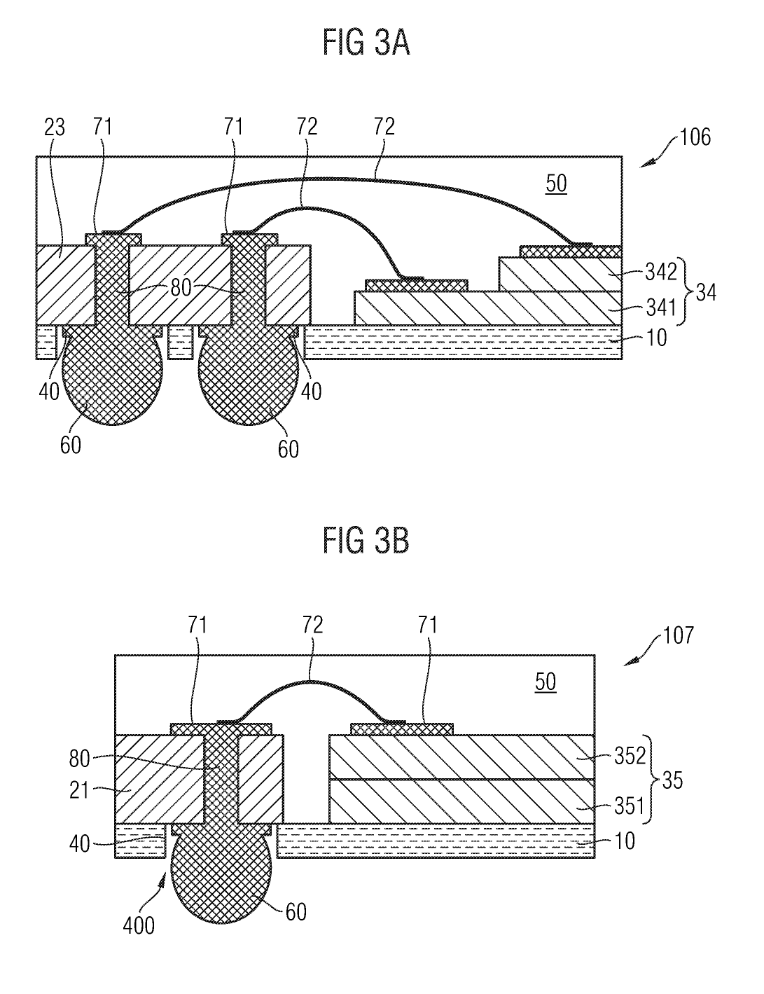

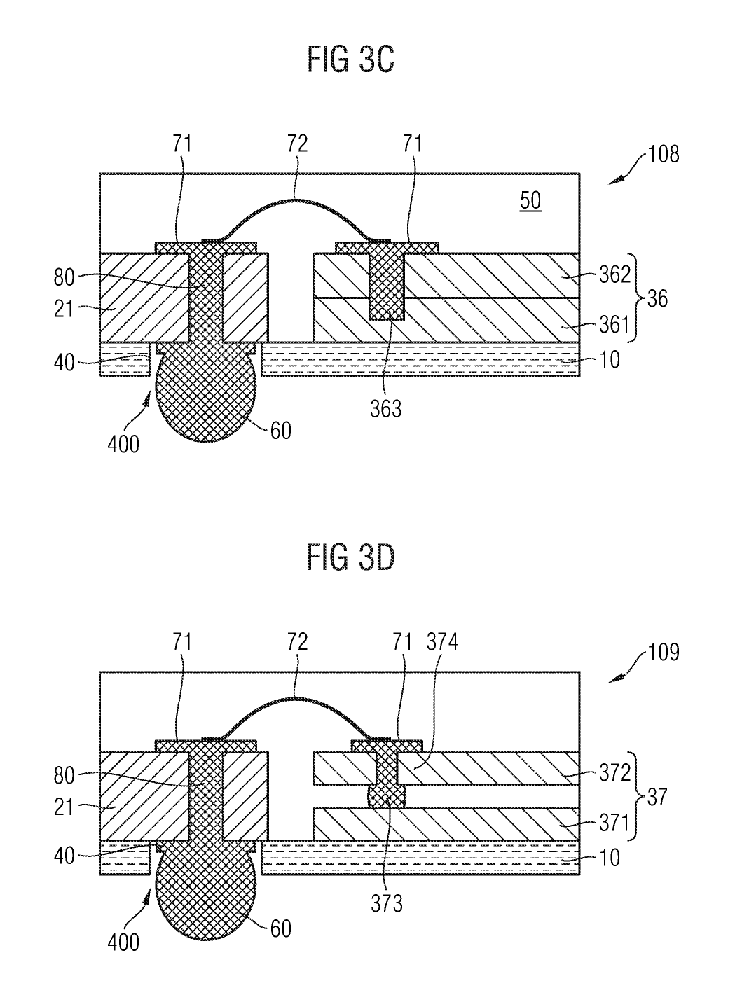

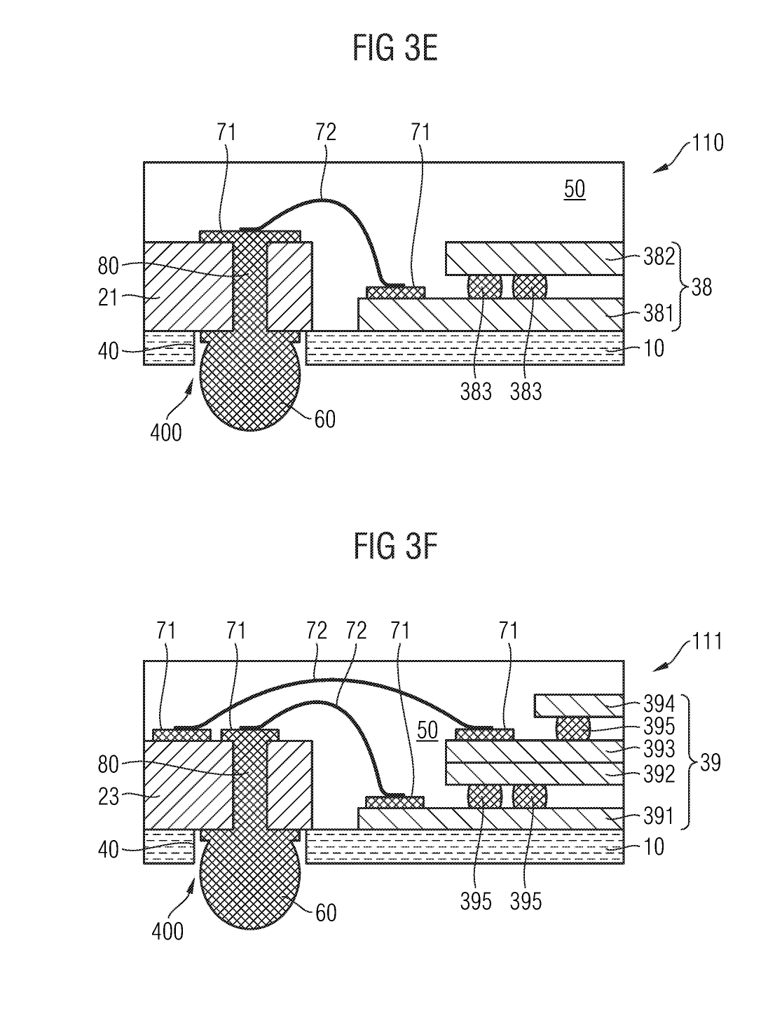

FIG. 3A shows a schematic cross-sectional view of an integrated circuit according to a seventh embodiment of the present invention. The integrated circuit 106 comprises a substrate stack 34, the stack 34 comprising a first circuit substrate 341 and a second circuit substrate 342. According to this embodiment, the second circuit substrate 342 is arranged on the first circuit substrate 341. The footprint and/or the positioning of the second circuit substrate 342 is such that a section of the first substrate 341 is exposed. In this way, a bond pad 71 may be arranged on a top surface of the first circuit substrate 341 and may be provided with a respective bond wire 72. In a similar manner, a bond pad 71 may be arranged on a top surface of the second circuit substrate 342, which may be provided with a respective bond wire 72. In this way, both substrates, the first circuit substrate 341 and the second circuit substrate 342 may be connected to corresponding bond pads 71, which are arranged on a top surface of the side substrate 23.

This may be an advantage, since several circuit substrates may be connected individually, without the need of interconnects, spacers, and the like between and/or amongst the individual circuit substrates of the stack 34.

FIG. 3B shows a schematic cross-sectional view of an integrated circuit according to an eighth embodiment of the present invention. According to this embodiment, an integrated circuit 107 comprises a substrate stack 35 comprising a first circuit substrate 351 and a second circuit substrate 352. The stack 35 may comprise means for interconnecting the individual constituent circuit substrates, such as the first circuit substrate 351 and/or the second circuit substrate 352. A bond pad 71 may be arranged on a top surface of the second circuit substrate 352, which may be provided with a respective bond wire 72. In this way, both substrates, by means of an interconnection among the constituent circuit substrates of the substrate stack 35, the constituent circuit substrates, may be connected to corresponding bond pads 71, which are arranged on a top surface of the side substrate 21.

FIG. 3C shows a schematic cross-sectional view of an integrated circuit according to a ninth embodiment. According to this embodiment, an integrated circuit 108 comprises a substrate stack 36 comprising a first circuit substrate 361 and a second circuit substrate 362. A via 363 interconnects the first circuit substrate 361 and/or the second circuit substrate 362 to a bond pad 71, which is arranged on a top surface of a top circuit substrate, such as the second circuit substrate 362. The via 363 may only connect the first circuit substrate 361 and may not connect any entities comprised by the second circuit substrate 362.

However, for example in the case the constituent circuit substrates of the substrate stack 36, such as the first circuit substrate 361 and the second circuit substrate 362, are of a same or a similar type, it may be of advantage to connect individual substrates in parallel. Hence, the via 363 may connect all or a part of the constituent substrates of the substrate stack 36 in parallel. This may be of advantage when the substrates are memory chips since several individual memory chips may be addressed in parallel, and, respective to their own address scope, may be selectively accessed. The top circuit substrate, such as the second circuit substrate 362 may be contacted without the need of a via, since a bond pad on a top surface of the second circuit substrate 362 may suffice for connection.

FIG. 3D shows a schematic cross-sectional view of an integrated circuit according to a tenth embodiment. According to this embodiment, an integrated circuit 109 comprises a substrate stack 37 comprising a first circuit substrate 371 and a second circuit substrate 372. According to this embodiment, the stack 37 comprises a flipchip stack, wherein two circuit substrates, such as the first circuit substrate 371 and the second circuit substrate 372 are stacked such that their top surfaces face each other.

In this way, an interconnection between the two circuit substrates may be effected by means of connections 373, connecting contact fields being arranged on the respective top surfaces of the circuit substrates 371, 372. Accordingly, a bond pad 71 is arranged on a bottom surface of the second circuit substrate 372 in order to allow for a connection of the stack 37 to the side substrate 21, by means of a bond wire 72. A via 374, such as a through-silicon via, may provide a connection from one side, e.g. the top surface, to another side, e.g. the bottom surface, of the circuit substrate 372. In this way, the first circuit substrate 371 may be connected by means of a bond pad 71 which is arranged on the second circuit substrate 372. A top circuit substrate, such as the second circuit substrate 372, may be connected with or without such a via 374.

FIG. 3E shows a schematic cross-sectional view of an integrated circuit according to an eleventh embodiment. According to this embodiment, an integrated circuit 110 comprises a substrate stack 38 comprising a first circuit substrate 381 and a second circuit substrate 382. According to this embodiment, the stack 38 comprises a flipchip stack, wherein two circuit substrates, such as the first circuit substrate 381 and the second circuit substrate 382 are stacked such that their top surfaces face each other. Furthermore, the footprint and/or the positioning of the second circuit substrate 382 is such that a section of the first substrate 381 is exposed.

In this way, a bond pad 71 may be arranged on a top surface of the first circuit substrate 381 and may be provided with a respective bond wire 72. In addition, the second circuit substrate 382 may be connected to a further bond pad 71, being arranged on the top surface of the first circuit substrate 381, by means of a connection 383 and a respective routing of the connection on the first circuit substrate 381 or on the second circuit substrate 382.

FIG. 3F shows a schematic cross-sectional view of an integrated circuit according to a twelfth embodiment. According to this embodiment, an integrated circuit 111 comprises the substrate stack 39 comprising at least a first circuit substrate 391, a second circuit substrate 392, a third circuit substrate 393, and a fourth circuit substrate 394. The stack 39 may further comprise more circuit substrates and/or more flipchip stacks of circuit substrates. A footprint and/or a positioning of the constituent circuit substrates 391, 392, 393, 394 is such that a section of a circuit substrate, for example a section of first circuit substrate 391 and a section of the third circuit substrate 393, is accessible. There, bond pads 71 may be arranged and connected to bond wires 72.

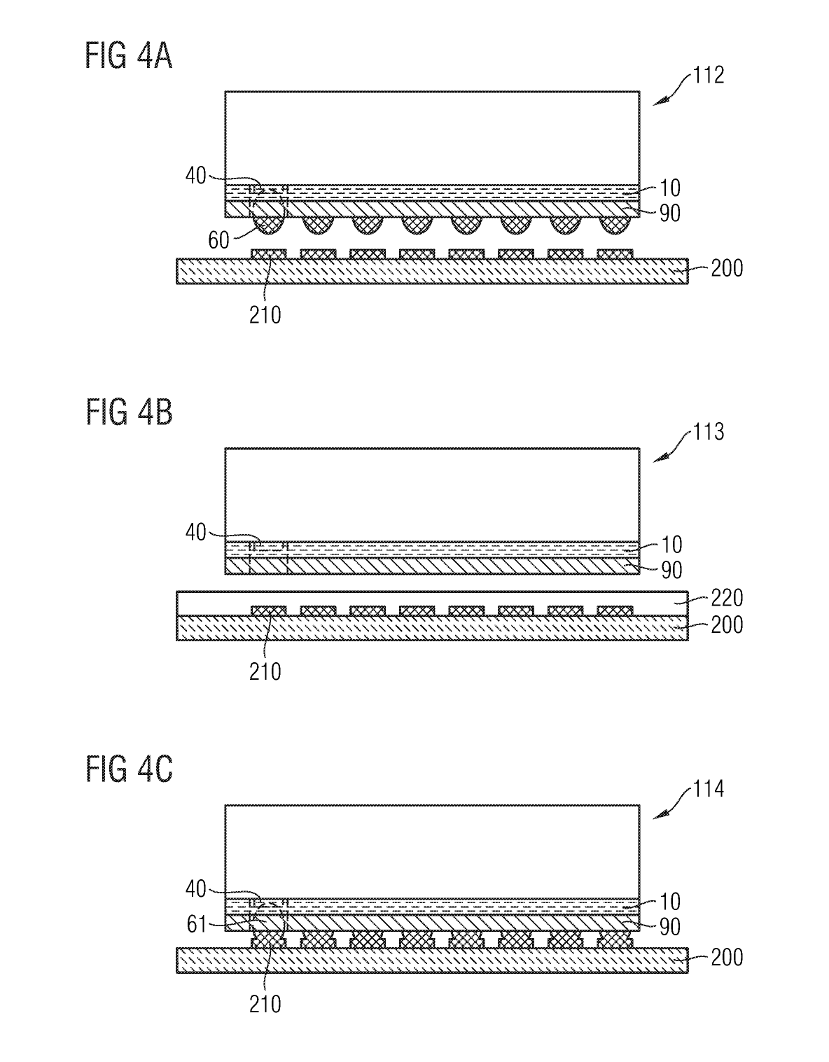

FIG. 4A shows a schematic view of an integrated circuit in conjunction with a circuit board according to a thirteenth embodiment. According to this embodiment, an integrated circuit 112 comprises a base layer 10, one or more circuit substrates, one or more side substrates, and respective connections which may be encapsulated by means of a package comprising a mold material. Circuit substrates, stacks thereof, side substrates, connections, mold materials, and combinations thereof are described in conjunction with other embodiments of the present invention. The integrated circuit 112 comprises a base layer 10 with openings, such to allow for a connection to side substrates and/or circuit substrates of the integrated circuit 112. Solder balls 60 are arranged in respective openings of the base layer 10 and are connected to respective contact fields of a side substrate. According to this embodiment, there is arranged a solder mask 90 on the base layer 10. The solder mask 90 restricts the wetting of a liquid solder material to the area of respective openings in the solder mask 90. Such openings may correspond to the respective openings of the base layer 10 in the field of the respective contact fields.

According to this embodiment, a circuit board 200, such as a printed circuit board, a motherboard, a memory module board, and/or a circuit system board, comprises contact pads 210 on a top surface of the circuit board 200. The size and position of the contact pads 210 may correspond to the size and position of the solder balls 60 and/or the contact fields 40 of the integrated circuit 112, such to allow for a plurality of interconnects between the integrated circuit 112 and the circuit board 200. The integrated circuit 112, according to this embodiment, may be brought into close vicinity of the circuit board 200 and may be soldered by means of a soldering process, such as wave soldering, infrared soldering, laser soldering, reflow soldering, and/or any other soldering techniques as they are known from the technology of manufacturing integrated circuit systems. For a possible arrangement comprising an integrated circuit and circuit board reference is made to the description in conjunction with FIG. 4C.

FIG. 4B shows a schematic view of an integrated circuit in conjunction with a circuit board according to a fourteenth embodiment. According to this embodiment, an integrated circuit 113 may just comprise the contact field 40 in a respective opening of the base layer 10 and/or the solder mask 90. No solder balls and/or any portions of a solderable material on the respective contact fields may be necessary, since a solder paste 220 is arranged on a top surface of the circuit board 200. The solder paste may provide the solderable material which is to form the connection between a contact field 40 and the corresponding contact pad 210 of the circuit board 200.

FIG. 4C shows a schematic view of an integrated circuit in conjunction with a circuit board according to a fifteenth embodiment. According to this embodiment, an integrated circuit 114, being, for example, the integrated circuit 112 or the integrated circuit 113, is soldered and connected to the circuit board 200 by means of solder connections 61. The solder connections 61 may have been formed by soldered solder balls 60 and/or a soldering with a solder paste 220. It is to be noted, that the arrangement, as shown in FIG. 4C, may be the result of the arrangements shown in conjunction with FIGS. 4A and 4B after soldering the integrated circuit to the circuit board.

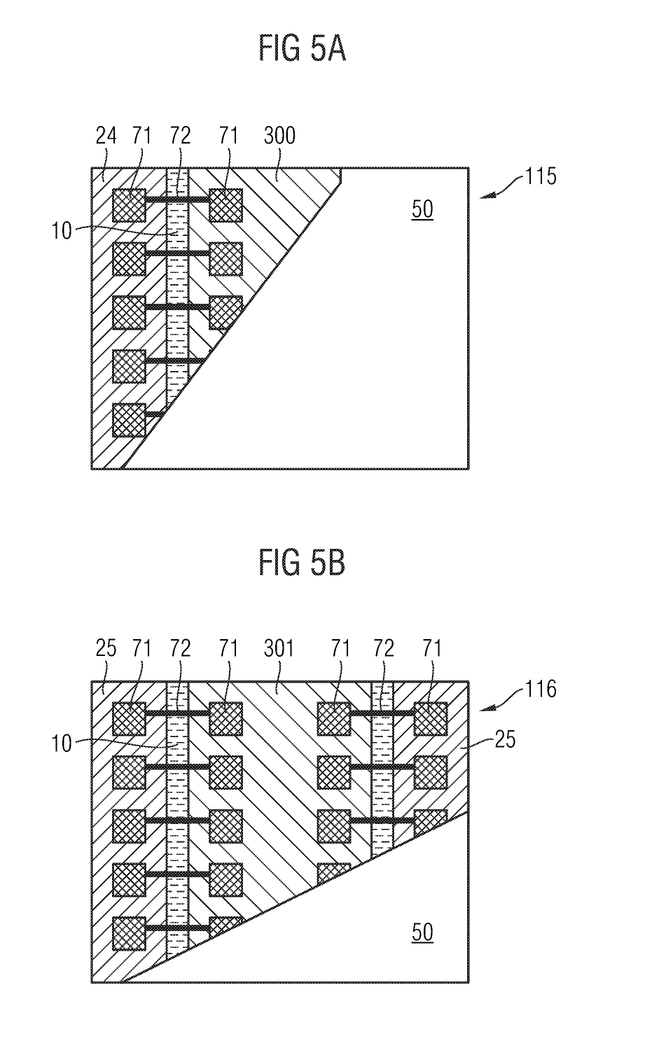

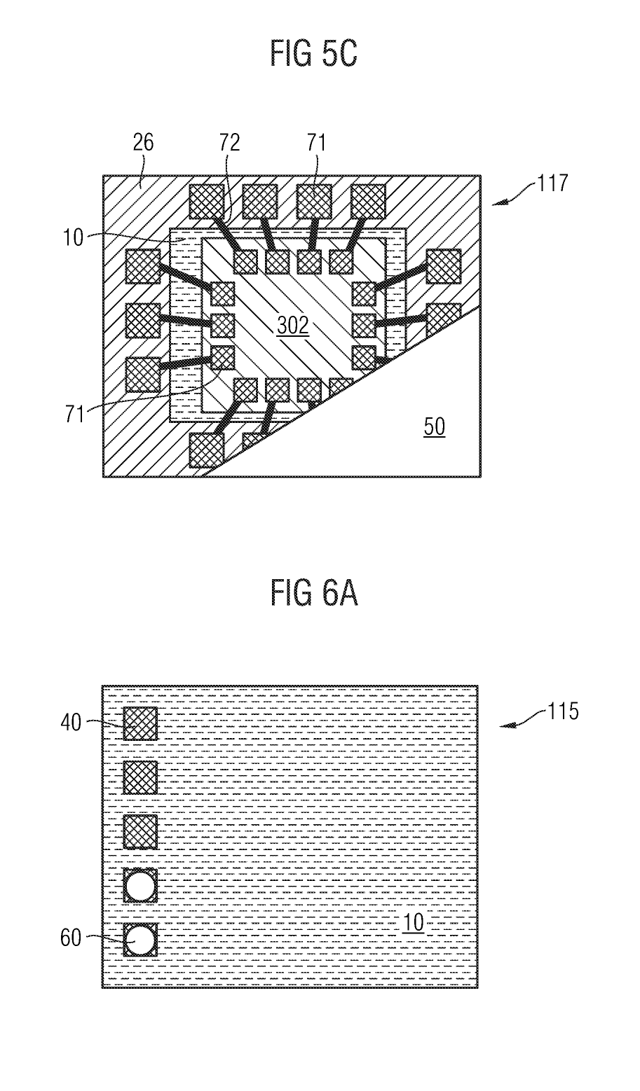

FIG. 5A shows a schematic top view of an integrated circuit according to a sixteenth embodiment of the present invention. According to this embodiment, an integrated circuit 115 comprises a circuit substrate 300 and/or a stack thereof. The circuit substrate 300 may comprise a circuit substrate and/or a substrate stack such as a circuit substrate or substrate stack 31 through 39 (described above).

For the sake of clarity, the integrated device 115 is shown partially opened, such that the mold material 50 exposes parts of the circuit substrate 300, a side substrate 24, and the base layer 10. In a completed device, however, the mold material 50 will cover all or most of the circuit substrate 300 and the side substrate 24, such that it encapsulates the integrated circuit. Facing bond pads 71 are connected by means of bond wires 72. According to this embodiment, the integrated circuit 115 comprises one side substrate 24 providing all necessary connections to the circuit substrate 300. In this way, the electrical connection is established by a single-side substrate which is held in place by means of the base layer 10 and/or the mold material 50. One or more rows of bond pads 71 may be arranged on the side substrate 24, which also applies to the circuit substrate 300.

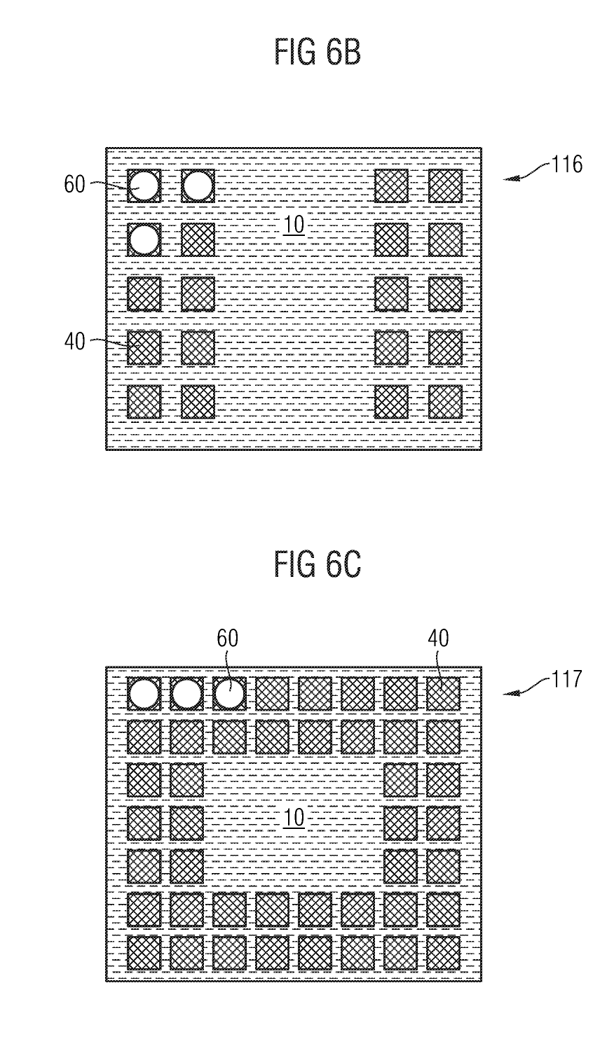

FIG. 6A shows a schematic bottom view of the integrated circuit 115. Accordingly, contact fields 40 are exposed along the side substrate 24 in areas of openings of the base layer 10. Furthermore, solder balls 60 may be arranged on all and/or a part of the contact fields 40, in order to provide a completed integrated circuit which may be soldered to a circuit board without the need of additional solder paste, such as a ball grid array (BGA) package. In addition to this, a solder mask may be arranged on the base layer 10 there.

FIG. 5B shows a schematic top view of an integrated circuit according to a seventeenth embodiment of the present invention. According to this embodiment, an integrated circuit 116 comprises a circuit substrate 301 and/or a stack thereof. Facing bond pads 71 are connected by means of bond wires 72 to two side substrates 25. According to this embodiment, the integrated circuit 116 comprises at least two side substrates 25 providing all necessary connections to the circuit substrate 301. The two side substrates 25 may be bar-like (i.e., rectangular and having a length that is longer than a width), and may be arranged alongside the circuit substrate 301 along parallel or perpendicular side faces. One or more rows of bond pads 71 may be arranged on the side substrates 25, which also applies to the circuit substrate 301.

FIG. 6B shows a schematic bottom view of the integrated circuit 116. Accordingly, contact fields 40 are exposed along the side substrates 25 in areas of openings of the base layer 10.

FIG. 5C shows a schematic top view of an integrated circuit according to a eighteenth embodiment of the present invention. According to this embodiment, an integrated circuit 117 comprises a circuit substrate 302 and/or a stack thereof. Facing bond pads 71 are connected by means of bond wires 72 to a side substrates 26. According to this embodiment, the integrated circuit 117 comprises a side substrate 26 with an opening. Illustratively, the side substrate 26 is rectangular with a central opening. Such a frame-like side substrate 26 may allow for an arrangement of the circuit substrate 302 in the opening of the side substrate 26.

Hence, the side substrate 26 may laterally surround the circuit substrate 302. The opening of the side substrate 26 may correspond in size and/or shape to the size and/or shape of the circuit substrate 302, such that the circuit substrate 302 may fit into the opening of the side substrate 26. Furthermore, the opening of side substrate 26 may be provided in size and or shape such that the circuit substrate 302 is mechanically held in place by the side substrate 26. This may involve the provision of the respective sizes and shapes with given tolerances. Such a tight fit provides mechanical stability, such that succeeding process stages, such as bonding, may be carried out, even without additional layers, such as the base layer 10. In general, the base layer and/or other entities may be omitted then.

FIG. 6C shows a schematic bottom view of the integrated circuit 117. Accordingly, contact fields 40 are exposed along the side substrates 26 in areas of openings of the base layer 10.

According to the embodiments of the present invention, a circuit substrate may also be denoted as chip or a die. A substrate may comprise a semiconductor material, such as silicon, and may possess a thickness below 200 microns, below 75, or below 50 microns. A thinning of a substrate may cause a warpage or surface irregularities, which may render further processing and/or alignment difficult or impossible. It may further impose problems in respect to wafer handling and/or processing.

Upon stacking circuit substrates in an integrated circuit, a further problem may be imposed by spreading heat in high density chip or chip packages. A direct contact to the constituent circuit substrates or to the substrate stack of an integrated circuit may provide an increased heat transfer and an improved cooling of the device. A base layer comprising a material with a high thermal conductance, such as silver, copper, or aluminium, may then be contacted directly to the substrate.

Thin packages may be required in mobile and/or hand-held applications, since space is rather limited there. An integrated circuit in a multichip package (MCP) or in a three-dimensional package (3D package) with a minimized total thickness may be required and accordingly provided then. According to the embodiments of the present invention chip stacking may be increased, i.e. more chips or substrates may be stacked, while maintaining a given footprint area. This may increase the performance of the integrated circuit.

According to the embodiments of the present invention, an additional metal layer, such as a copper layer, may be arranged on top of a side substrate and an additional solder mask on top of the additional metal layer may be provided.

The preceding description only describes exemplary embodiments of the invention. The features disclosed therein and the claims and the drawings can, therefore, be important for the realisation of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

1. An integrated circuit, comprising:
a base layer forming at least an opening;
a side substrate defining at least a first and second face, wherein the first face is disposed on the base layer; the side substrate comprising a first contact field, at least a second contact field, and a signal line, the first contact field being disposed on the first face in an area of the opening of the base layer, the second contact field being disposed on the second face, and the signal line connecting the first contact field to the second contact field;
a circuit substrate disposed on the base layer and alongside the side substrate; and
a connection, the connection connecting the circuit substrate to the second contact field of the side substrate.

2. The integrated circuit as claimed in claim 1, the side substrate forming an opening and the circuit substrate being disposed on the base layer inside the opening of the side substrate.

3. The integrated circuit as claimed in claim 1, further comprising a solder ball disposed on the first contact field of the side substrate.

4. The integrated circuit as claimed in claim 1, further comprising a stack of at least two circuit substrates, the stack comprising the circuit substrate.

5. The integrated circuit as claimed in claim 4, wherein the at least two circuit substrates of the stack are connected by a flipchip bond.

6. The integrated circuit as claimed in claim 1, further comprising at least one further circuit substrate disposed on the circuit substrate, the further circuit substrate having a smaller footprint than the circuit substrate and exposing a section of a top surface of the circuit substrate.

7. The integrated circuit as claimed in claim 6, further comprising a stack of at least two circuit substrates, the stack comprising the circuit substrate and wherein the at least two circuits of the stack are connected by a flipchip bond.

8. The integrated circuit as claimed in claim 1, wherein the circuit substrate comprises a bond pad and the connection comprises a bond wire bonded to the bond pad and to the second contact field of the side substrate.

9. The integrated circuit as claimed in claim 1, wherein the base layer comprises a metal layer.

10. The integrated circuit as claimed in claim 9, wherein the metal is selected from the group of copper, aluminium, tin, lead, bismuth, and silver.

11. The integrated circuit as claimed in claim 1, wherein the base layer comprises a solder mask on a bottom face.

12. The integrated circuit as claimed in claim 1, further comprising an encapsulation disposed about the integrated circuit.

13. An integrated circuit, comprising:
a base layer forming a first opening;
a side substrate defining a second opening, a first face and a second face, the first face being disposed on the base layer; the side substrate comprising a first contact field, at least a second contact field, and a signal line, the first contact field being disposed on the first face in an area of the first opening, the second contact field being disposed on the second face of the side substrate, and the signal line connecting the first contact field to the second contact field;
a substrate stack comprising at least two circuit substrates, the substrate stack being disposed on the base layer and inside the second opening; and
a connection, the connection connecting a circuit substrate of the substrate stack to the second contact field of the side substrate.

14. The integrated circuit as claimed in claim 13, further comprising a solder ball disposed on the first contact field of the side substrate.

15. The integrated circuit as claimed in claim 13, wherein the at least two circuit substrates of the stack are connected by a flipchip bond.

16. The integrated circuit as claimed in claim 13, wherein the substrate stack comprises a first circuit substrate and a second circuit substrate, the second circuit substrate being disposed on the first circuit substrate, having a smaller footprint than the first circuit substrate, and exposing a section of a top surface of the first circuit substrate.

17. The integrated circuit as claimed in claim 13, wherein a circuit substrate of the substrate stack comprises a bond pad and the connection comprises a bond wire, the bond wire being bonded to the bond pad and to the second contact field of the side substrate.

18. The integrated circuit as claimed in claim 13, wherein the base layer comprises a metal layer.

19. The integrated circuit as claimed in claim 18, wherein the metal is selected from the group of copper, aluminium, tin, lead, bismuth, and silver.

20. The integrated circuit as claimed in claim 13, the base layer comprising a solder mask on the first face.

21. The integrated circuit as claimed in claim 13, wherein the integrated device comprises an encapsulation.

22. An integrated memory device, comprising:
a base layer, the base layer defining a first opening;
a side substrate defining a second opening, a first face and second face, the first and the second faces being opposite one another; wherein the first face is disposed on the base layer; the side substrate comprising a contact field, a first bond pad, and a signal line, the contact field being disposed on the first face in an area of the first opening of the base layer, the first bond pad being disposed on the second face of the side substrate, and the signal line connecting the contact field to the first bond pad;
a chip stack comprising at least two memory chips substrates, the chip stack being disposed on the base layer and inside the second opening, a memory chip of the chip stack comprising a second bond pad on a first face of the memory chip;
a bond wire, the bond wire connecting the first bond pad of the side substrate to the second bond pad of the memory chip of the chip stack; and
an encapsulation material disposed on the chip stack, the side substrate, the base layer, and the bond wire.

23. The integrated memory device as claimed in claim 22, further comprising a solder ball disposed on the contact field of the side substrate.

24. The integrated memory device as claimed in claim 22, wherein the base layer comprises a metal layer.

25. The integrated memory device as claimed in claim 24, wherein the metal is selected from the group of copper, aluminium, tin, lead, bismuth, and silver.

26. The integrated memory device as claimed in claim 22, wherein the base layer comprises a solder mask on a bottom face.

27. The integrated memory device as claimed in claim 22, wherein two memory chips of the chip stack are connected by a flipchip bond.

28. The integrated memory device as claimed in claim 22, wherein the chip stack comprises at least a first memory chip and a second memory chip, the second memory chip being disposed on the first memory chip, having a smaller footprint than the first memory chip, and exposing a section of a top surface of the first memory chip.
